(19) United States
(12) Patent Application Publication
(10) Pub. No.: US 2023/0227601 A1
(43) Pub. Date: Jul. 20, 2023

(54) EPOXY RESIN COMPOSITION AND CURED PRODUCT THEREOF

(71) Applicants: NIPPON STEEL Chemical & Material Co., Ltd., Tokyo (JP); KUKDO CHEMICAL CO., LTD., Seoul (KR)

(72) Inventors: Masahiro SOH, Tokyo (JP); Kazuo ISHIHARA, Tokyo (JP); KIHWAN YU, Seoul (KR); CHEONGRAE LIM, Seoul (KR)

(73) Assignees: NIPPON STEEL Chemical & Material Co., Ltd., Tokyo (JP); KUKDO CHEMICAL CO., LTD., Seoul (KR)

(21) Appl. No.: 18/007,746

(22) PCT Filed: May 28, 2021
(86) PCT No.: PCT/JP2021/020524

§ 371 Date: Dec. 2, 2022

(30) Foreign Application Priority Data
Jun. 4, 2020 (JP) 2020-097542

(51) Int. Cl. C08G 59/32; C08J 5/24; H05K 1/03

(52) U.S. Cl. CPC C08G 59/3218; C08J 5/24; H05K 1/0326; C08J 2363/00

(57) ABSTRACT

To provide an epoxy resin composition that exhibits excellent low-dielectric properties and that is excellent in copper foil peel strength and interlayer cohesion strength in a printed-wiring board application. An epoxy resin composition containing an epoxy resin and a curing agent, wherein the epoxy resin is partially or fully an epoxy resin represented by the following general formula (1). Each R¹ represents a hydrocarbon group having 1 to 8 carbon atoms, each R² represents a hydrogen atom or a dicyclopentenyl group, and at least one R² is a dicyclopentenyl group; and m represents a number of 0 to 5.

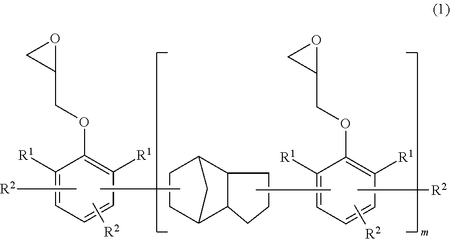

### TECHNICAL FIELD

The present invention relates to an epoxy resin composition, an epoxy resin-cured product, a prepreg, a laminated board, and a printed-wiring substrate, which are excellent in low-dielectric properties and high adhesiveness.

### BACKGROUND ART

Epoxy resins are excellent in adhesiveness, flexibility, heat resistance, chemical resistance, insulation properties and curing reactivity, and thus are used variously in paints, civil adhesion, cast molding, electrical and electronic materials, film materials, and the like. In particular, epoxy resins, to which flame retardance is imparted, are widely used in applications of printed-wiring substrates as one of electrical and electronic materials.

In recent years, information equipment has been rapidly progressively reduced in size and increased in performance, and materials for use in the fields of semiconductors and electronic components have been accordingly demanded to have higher performance than even before. In particular, epoxy resin compositions serving as materials for electrical and electronic components have been demanded to have low-dielectric properties along with thinning and functionalization of substrates.

Dicyclopentadiene phenol resins and the like having aliphatic backbones introduced have been heretofore used for reduction in permittivity in laminated board applications as shown in Patent Literature 1 below. However, these resins are less effective for improvement in dielectric tangent and have no satisfiable adhesiveness.

Aromatic modified epoxy resins and the like having aromatic backbone introduced have been used as resins for providing low dielectric tangent as shown in Patent Literature 2 below. However, these resins, while provide dielectric tangent, have the problem of being deteriorated in adhesion force, and there is a demand for development of a resin providing low dielectric tangent and high adhesion force.

Both the epoxy resins disclosed in the Literatures listed above have not sufficiently satisfied requirements based on recent increases in functions, and have been insufficient for retaining low-dielectric properties and adhesiveness.

On the other hand, Patent Literature 3 has disclosed a 2,6-disubstituted phenol/dicyclopentadiene-type resin, but has not disclosed any resin where substitution with a plurality of dicyclopentadienes is made on a phenol ring.

### CITATION LIST

### Patent Literatures

Patent Literature 1: Japanese Patent Laid-Open No. 2001-240654

Patent Literature 2: Japanese Patent Laid-Open No. 2015-187190

Patent Literature 3: Japanese Patent Laid-Open No. 5-339341

### SUMMARY OF INVENTION

Accordingly, a problem to be solved by the present invention is to provide an epoxy resin composition that allows a cured product to exhibit excellent dielectric tangent and furthermore that is excellent in copper foil peel strength and interlayer cohesion strength in a printed-wiring board application.

In order to solve the above problem, the present inventors have found that, in a case where an epoxy resin obtained by epoxidation of a phenol resin obtained by a reaction of a 2,6-disubstituted phenol compound with dicyclopentadiene at a specified ratio cured with a curing agent, a cured product obtained is excellent in low-dielectric properties and adhesiveness, thereby completing the present invention.

In other words, the present invention relates to an epoxy resin composition containing an epoxy resin and a curing agent, wherein the epoxy resin is partially or fully an epoxy resin represented by the following general formula (1):

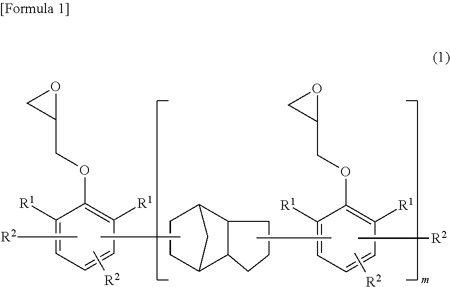

wherein R¹ independently represents a hydrocarbon group having 1 to 8 carbon atoms, R² independently represents a hydrogen atom, or a dicyclopentenyl group, and at least one is the dicyclopentenyl group; and m represents the number of repetitions and an average value thereof is a number of 0 to 5.

The epoxy resin preferably has an epoxy equivalent of 244 to 3700 g/eq.

The curing agent is preferably at least one of a phenol resin compound, an acid anhydride compound, an amine compound, a cyanate ester compound, an active ester compound, a hydrazide compound, an acidic polyester compound, or an aromatic cyanate compound.

The present invention also relates to a cured product obtained by cuing the epoxy resin composition. The present invention further relates to a prepreg, a laminated board or a printed-wiring substrate using the epoxy resin composition.

The epoxy resin composition of the present invention allows a cured product thereof to exhibit excellent dielectric tangent, and furthermore is excellent in copper foil peel strength and interlayer cohesion strength in a printed-wiring board application. In particular, the epoxy resin composition can be suitably used in, for example, a mobile application or and server application, in which a low dielectric tangent is strongly required.

### BRIEF DESCRIPTION OF DRAWINGS

FIG. 1 A GPC chart of a polyvalent hydroxy compound obtained in Synthesis Example 1.

FIG. 2 An IR chart of the polyvalent hydroxy compound obtained in Synthesis Example 1.

FIG. 3 A GPC chart of an epoxy resin obtained in Synthesis Example 4.

### DESCRIPTION OF EMBODIMENTS

Hereinafter, embodiments of the present invention will be described in detail.

The epoxy resin for use in the epoxy resin composition of the present invention is represented by the general formula (1).

In the general formula (1), R¹ represents a hydrocarbon group having 1 to 8 carbon atoms. Preferably R¹ is an alkyl group having 1 to 8 carbon atoms, an aryl group having 6 to 8 carbon atoms, an aralkyl group having 7 to 8 carbon atoms, or an allyl group. The alkyl group having 1 to 8 carbon atoms may be any of linear, branched and cyclic groups, and examples thereof include a methyl group, an ethyl group, a propyl group, an isopropyl group, a n-butyl group, a t-butyl group, a hexyl group, a cyclohexyl group and a methylcyclohexyl group, but not limited thereto. Examples of the aryl group having 6 to 8 carbon atoms include a phenyl group, a tolyl group, a xylyl group and an ethylphenyl group, but not limited thereto. Examples of the aralkyl group having 7 to 8 carbon atoms include a benzyl group and an α-methylbenzyl group, but not limited thereto. A phenyl group or a methyl group is preferable and a methyl group is more preferable from the viewpoints of availability, and reactivity of a cured product obtained.

Each R² independently represents a hydrogen atom or a dicyclopentenyl group, and at least one R² in its molecule is a dicyclopentenyl group. The dicyclopentenyl group is a group derived from dicyclopentadiene, and is represented by the following formula (1a) or formula (1b). A cured product of the epoxy resin composition of the present invention can be reduced in permittivity and dielectric tangent due to the presence of the group.

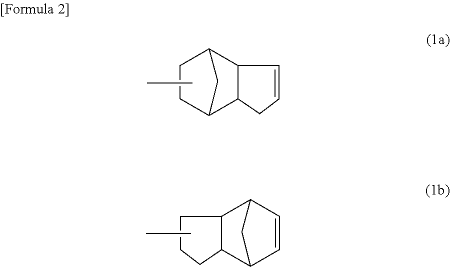

m is the number of repetitions and represents a number of 0 or more, and the average value (number average) thereof is 0 to 5, preferably 0.5 to 3, more preferably 0.5 to 2, further preferably 0.6 to 1.8. A usual epoxy resin is a mixture of components different in m, and R² in this case may be such that at least one R² on average in one molecule is the dicyclopentenyl group. A reaction product where each R² fully corresponds to a hydrogen atom may be here mixed.

In GPC, preferably, the content of an m=0 form is in the range of 10% by area or less, the content of an m=1 form is in the range of 50 to 80% by area, and the content of an m≥2 form is in the range of 20 to 40% by area.

The epoxy resin represented by the general formula (1) can be obtained by, for example, reacting a polyvalent hydroxy compound (hereinafter, also referred to as “phenol resin”) of the following general formula (2) with epihalohydrin such as epichlorohydrin. The reaction is performed according to a conventionally known method.

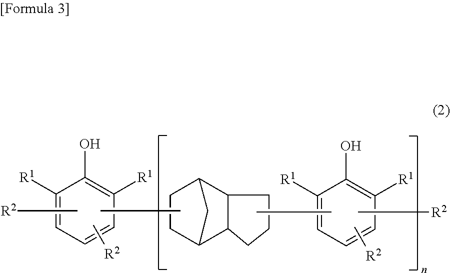

In the general formula (2), R¹ and R² have the same meanings as in the formula (1).

n is the number of repetitions and represents a number of 0 or more, and the average value (number average) thereof is 0 to 5, preferably 0.5 to 3, more preferably 0.6 to 2, further preferably 0.6 to 1.8. In GPC, preferably, the content of an n=0 form is in the range of 10% by area or less, the content of an n=1 form is in the range of 50 to 80% by area, and the content of an n≥2 form is in the range of 10 to 40% by area.

The polyvalent hydroxy compound preferably has a hydroxyl group equivalent of 230 or more, more preferably 240 or more, and preferably has a softening point of 120° C. or less, more preferably 110° C. or less. The polyvalent hydroxy compound preferably has a weight average molecular weight (Mw) in the range of 400 to 1000 and preferably has a number average molecular weight (Mn) in the range of 350 to 800.

The polyvalent hydroxy compound can be obtained by a reaction of a 2,6-disubstituted phenol compound with dicyclopentadiene in the presence of a Lewis acid such as a boron trifluoride/ether catalyst.

Examples of the 2,6-disubstituted phenol compound include 2,6-dimethylphenol, 2,6-diethylphenol, 2,6-dipropylphenol, 2,6-diisopropylphenol, 2,6-di(n-butyl)phenol, 2,6-di(t-butyl)phenol, 2,6-dihexylphenol, 2,6-dicyclohexylphenol, 2,6-diphenylphenol, 2,6-ditolylphenol, 2,6-dibenzylphenol, 2,6-bis(α-methylbenzyl)phenol, 2-ethyl-6-methylphenol, 2-allyl-6-methylphenol and 2-tolyl-6-phenylphenol, and 2,6-diphenylphenol and 2,6-dimethylphenol are preferable and 2,6-dimethylphenol is particularly preferable from the viewpoints of availability, and reactivity of a cured product obtained.

The catalyst for use in the reaction is a Lewis acid, is specifically, for example, boron trifluoride, a boron trifluoride/phenol complex, a boron trifluoride/ether complex, aluminum chloride, tin chloride, zinc chloride or iron chloride, and in particular, a boron trifluoride/ether complex is preferable in terms of ease of handling. In the case of a boron trifluoride/ether complex, the amount of the catalyst used is 0.001 to 20 parts by mass, preferably 0.5 to 10 parts by mass based on 100 parts by mass of the dicyclopentadiene.

The reaction method for introducing the dicyclopentadiene structure of the formula (1a) or formula (1b) into the 2,6-disubstituted phenol compound is a method for reacting dicyclopentadiene with 2,6-disubstituted phenol at a predetermined ratio, and the dicyclopentadiene may be intermittently reacted at multiple stages. The ratio of the dicyclopentadiene to the 2,6-disubstituted phenol is 0.1 to 0.25-fold moles in a common reaction, whereas the ratio is 0.28 to 2-fold moles in the present invention. When the dicyclopentadiene is continuously added and reacted, the ratio of the dicyclopentadiene relative to the 2,6-disubstituted phenol is preferably 0.28 to 1-fold moles, more preferably 0.3 to 0.5-fold moles. When the dicyclopentadiene is intermittently added at multiple stages and thus reacted, the ratio is preferably 0.8 to 2-fold moles, more preferably 0.9 to 1.7-fold moles. The amount of the dicyclopentadiene used at each stage is preferably 0.28 to 1-fold moles.

The method of confirming introduction of the dicyclopentenyl group represented by the formula (1a) or formula (1b) into the polyvalent hydroxy compound represented by the general formula (2) can be made by using mass spectrometry or FT-IR measurement.

In the case of use of mass spectrometry, for example, electrospray mass spectrometry (ESI-MS) or a field desorption method (FD-MS) can be used. The introduction of the substituent represented by the formula (1a) or formula (1b) can be confirmed by subjecting a sample where components different in number of nuclei are separated in GPC or the like, to mass spectrometry.

In the case of use of a FT-IR measurement method, a KRS-5 cell is coated with a sample dissolved in an organic solvent such as THF and such a cell provided with a thin film of the sample, obtained by drying the organic solvent, is subjected to FT-IR measurement, and thus a peak assigned to C—O stretching vibration of a phenol nucleus appears around 1210 cm⁻¹ and a peak assigned to C—H stretching vibration of an olefin moiety of a dicyclopentadiene backbone appears around 3040 cm⁻¹ only in the case of introduction of the formula (1a) or formula (1b). When one obtained by linearly connecting the start and the end of an objective peak is defined as a baseline and the length from the top of the peak to the baseline is defined as a peak height, the amount of introduction of the formula (1a) or formula (1b) can be quantitatively determined by the ratio (A₃₀₄₀/A₁₂₁₀) of the peak (A₃₀₄₀) around 3040 cm⁻¹ to the peak (A₁₂₁₀) around 1210 cm⁻¹. It can be confirmed that, as the ratio is higher, the values of physical properties are more favorable, and a preferable ratio (A₃₀₄₀/A₁₂₁₀) for satisfaction of objective physical properties is 0.05 or more, more preferably 0.10 or more.

The present reaction is favorably made in a manner where the 2,6-disubstituted phenol compound and the catalyst are loaded into a reactor and the dicyclopentadiene is dropped over 1 to 10 hours.

The reaction temperature is preferably 50 to 200° C., more preferably 100 to 180° C., further preferably 120 to 160° C. The reaction time is preferably 1 to 10 hours, more preferably 3 to 10 hours, further preferably 4 to 8 hours.

After completion of the reaction, the catalyst is deactivated by addition of an alkali such as sodium hydroxide, potassium hydroxide, or calcium hydroxide. Thereafter, a solvent, for example, an aromatic hydrocarbon compound such as toluene or xylene or a ketone compound such as methyl ethyl ketone or methyl isobutyl ketone is added for dissolution, the resultant is washed with water, thereafter the solvent is recovered under reduced pressure, and thus an objective phenol resin can be obtained. Preferably, the dicyclopentadiene is reacted in the entire amount as much as possible and some, preferably, 10% or less of the 2,6-disubstituted phenol compound is unreacted and recovered under reduced pressure.

During the reaction, a solvent, for example, an aromatic hydrocarbon compound such as benzene, toluene or xylene, a halogenated hydrocarbon compound such as chlorobenzene or dichlorobenzene, or an ether compound such as ethylene glycol dimethyl ether or diethylene glycol dimethyl ether may be, if necessary, used.

The epoxy resin represented by the general formula (1) can be obtained by, for example, epoxidation of the phenol resin. The epoxidation method can be made by, for example, addition of an alkali metal hydroxide such as sodium hydroxide in the form of a solid or an aqueous concentrated solution to a mixture of the phenol resin and an excess mole of epihalohydrin relative to the hydroxyl group of the phenol resin and a reaction at a reaction temperature of 30 to 120° C. for 0.5 to 10 hours, or addition of a quaternary ammonium salt such as tetraethylammonium chloride as a catalyst to the phenol resin and an excess mole of epihalohydrin, addition of an alkali metal hydroxide such as sodium hydroxide as a solid or an aqueous concentrated solution to polyhalohydrin ether obtained from a reaction at a temperature of 50 to 150° C. for 1 to 5 hours, and a reaction at a temperature of 30 to 120° C. for 1 to 10 hours.

The amount of epihalohydrin used in the reaction, relative to the hydroxyl group of the phenol resin, is 1 to 20-fold moles, preferably 2 to 8-fold moles. The amount of the alkali metal hydroxide used, relative to the hydroxyl group of the phenol resin, is 0.85 to 1.15-fold moles.

The epoxy resin obtained by such a reaction includes the unreacted epihalohydrin and alkali metal halide, thus the unreacted epihalohydrin is evaporated and removed and furthermore the alkali metal halide is removed by method(s) such as extraction with water and/or separation by filtration, from the reaction mixture, and thus an objective epoxy resin can be obtained.

The epoxy equivalent (g/eq.) of the epoxy resin is preferably 250 or more, more preferably 300 or more, further preferably 350 or more. In particular, when dicyandiamide is used as a curing agent, the epoxy equivalent is preferably 300 or more in order to prevent a dicyandiamide crystal from being precipitated on a prepreg.

The epoxy resin preferably has a softening point of 100° C. or less, more preferably 90° C. or less. The total content of chlorine is preferably 1000 ppm or less, more preferably 700 ppm or less.

A molecular weight distribution of the epoxy resin can be changed by the change in loading ratio of the phenol resin and epihalohydrin during the epoxidation reaction, and, as the amount of epihalohydrin is closer to an equal mole to that of the hydroxyl group of the phenol resin, a higher molecular weight distribution is obtained, and, as the amount is closer to 20-fold moles, a lower molecular weight distribution is obtained. For example, an epoxy resin having a weight average molecular weight (Mw) in the range of 500 to 1000 and having a number average molecular weight (Mn) in the range of 400 to 800 can be obtained. The epoxy resin obtained can also be increased in molecular weight by the action of the phenol resin again.

The epoxy resin can be used to thereby obtain the epoxy resin composition of the present invention.

The epoxy resin composition of the present invention includes the epoxy resin represented by the general formula (1) and a curing agent, as essential components. Various epoxy resins may be, if necessary, used, in addition to the epoxy resin as an essential component, singly or in combinations of two or more kinds thereof. When such other epoxy resin is used in combination, the proportion of such other epoxy resin in the entire epoxy resin is preferably 70% by mass or less, more preferably 50% by mass or less. If the proportion of such other epoxy resin is too high, the epoxy resin composition may have degraded dielectric properties.

Any common epoxy resin having two or more epoxy groups in its molecule can be used as such other epoxy resin. Examples include a bisphenol A-type epoxy resin, a bisphenol F-type epoxy resin, a bisphenol AF-type epoxy resin, a tetramethyl bisphenol F-type epoxy resin, a hydroquinone-type epoxy resin, a biphenyl-type epoxy resin, a stilbene-type epoxy resin, a bisphenol fluorene-type epoxy resin, a bisphenol S-type epoxy resin, a bisthio ether-type epoxy resin, a resorcinol-type epoxy resin, a biphenylaralkylphenol-type epoxy resin, a naphthalene diol-type epoxy resin, a phenol novolac-type epoxy resin, an aromatic modified phenol novolac-type epoxy resin, a cresol novolac-type epoxy resin, an alkyl novolac-type epoxy resin, a bisphenol novolac-type epoxy resin, a binaphthol-type epoxy resin, a naphthol novolac-type epoxy resin, a β-naphtholaralkyl-type epoxy resin, a dinaphtholaralkyl-type epoxy resin, an α-naphtholaralkyl-type epoxy resin, a trifunctional epoxy resin such as a trisphenylmethane-type epoxy resin, a tetrafunctional epoxy resin such as a tetrakisphenylethane-type epoxy resin, a dicyclopentadiene-type epoxy resin (except for the resin included in the general formula (1)), polyhydric alcohol polyglycidyl ether such as 1,4-butane diol diglycidyl ether, 1,6-hexane diol diglycidyl ether, glycerol polyglycidyl ether, trimethylolpropane polyglycidyl ether, trimethylolethane polyglycidyl ether and pentaerythritol polyglycidyl ether, an alkylene glycol-type epoxy resin such as propylene glycol diglycidyl ether, an aliphatic cyclic epoxy resin such as cyclohexane dimethanol diglycidyl ether, a glycidyl ester compound such as dimer acid polyglycidyl ester, a glycidyl amine-type epoxy resin such as phenyl diglycidyl amine, tolyl diglycidyl amine, diaminodiphenylmethane tetraglycidyl amine and an aminophenol-type epoxy resin, an alicyclic epoxy resin such as Celloxide 2021P (manufactured by Daicel Corporation), a phosphorus-containing epoxy resin, a bromine-containing epoxy resin, a urethane-modified epoxy resin, and an oxazolidone ring-containing epoxy resin, but not limited thereto. An epoxy resin represented by the following general formula (3), a dicyclopentadiene-type epoxy resin (except for the resin included in the general formula (1)), a naphthalene diol-type epoxy resin, a phenol novolac-type epoxy resin, an aromatic modified phenol novolac-type epoxy resin, a cresol novolac-type epoxy resin, an α-naphtholaralkyl-type epoxy resin, a dicyclopentadiene-type epoxy resin, a phosphorus-containing epoxy resin, and an oxazolidone ring-containing epoxy resin are further preferably used from the viewpoint of availability.

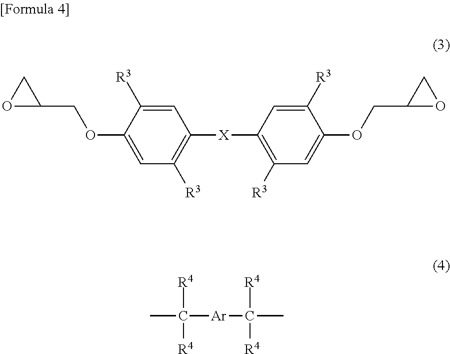

Each R³ independently represents a hydrocarbon group having 1 to 8 carbon atoms, and is, for example, an alkyl group such as a methyl group, an ethyl group, a n-propyl group, an isopropyl group, a n-butyl group, a t-butyl group, a n-hexyl group or a cyclohexyl group, and these may be the same as or different from each other.

X represents a divalent group, and represents, for example, an alkylene group such as a methylene group, an ethylene group, an isopropylene group, an isobutylene group or a hexafluoroisopropylidene group, —CO—, —O—, —S—, —SO₂—, —S—S—, or an aralkylene group represented by formula (4).

Each R⁴ independently represents a hydrogen atom or a hydrocarbon group having 1 or more carbon atoms, for example, a methyl group, and these may be the same as or different from each other.

Ar represents a benzene ring or a naphthalene ring, and such a benzene ring or naphthalene ring may have an alkyl group having 1 to 10 carbon atoms, an alkoxy group having 1 to 10 carbon atoms, an aryl group having 6 to 11 carbon atoms, an aralkyl group having 7 to 12 carbon atoms, an aryloxy group having 6 to 11 carbon atoms or an aralkyloxy group having 7 to 12 carbon atoms, as a substituent.

Various curing agents usually used, such as a phenol resin compound, an acid anhydride compound, an amine compound, a cyanate ester compound, an active ester compound, a hydrazide compound, an acidic polyester compound and an aromatic cyanate compound, can be, if necessary, used as a curing agent, singly or in combinations of two or more kinds thereof.

The molar ratio of the active hydrogen group of the curing agent per mol of the epoxy group in the entire epoxy resin, in the epoxy resin composition of the present invention, is preferably 0.2 to 1.5 mol, more preferably 0.3 to 1.4 mol, further preferably 0.5 to 1.3 mol, particularly preferably 0.8 to 1.2 mol. If the number of moles does not fall within such a range, curing is incomplete and no favorable physical properties of a cured product may be obtained. For example, when a phenol resin-based curing agent or an amine-based curing agent is used, the active hydrogen group and the epoxy group are compounded in almost equimolar amounts. When an acid anhydride-based curing agent is used, the number of moles of the acid anhydride group compounded per mol of the epoxy group is 0.5 to 1.2 mol, preferably 0.6 to 1.0 mol. When the phenol resin of the present invention is singly used as a curing agent, the active ester resin is desirably used in the range from 0.9 to 1.1 mol per mol of the epoxy resin.

The active hydrogen group mentioned in the present invention means a functional group having active hydrogen reactive with an epoxy group (encompassing a functional group having potentially active hydrogen which generates active hydrogen by hydrolysis or the like, and a functional group exhibiting equivalent curing action), and specific examples include an acid anhydride group, a carboxyl group, an amino group and a phenolic hydroxyl group. Herein, 1 mol of a carboxyl group or a phenolic hydroxyl group is considered to correspond to 1 mol of the active hydrogen group and 1 mol of an amino group (NH₂) is considered to correspond to 2 mol of the active hydrogen group. When the active hydrogen group is not clear, the active hydrogen equivalent can be determined by measurement. For example, the active hydrogen equivalent of a curing agent used can be determined by a reaction of a monoepoxy resin having a known epoxy equivalent, such as phenyl glycidyl ether, and a curing agent having an unknown active hydrogen equivalent and then measurement of the amount of the monoepoxy resin consumed.

Specific examples of the phenol resin-based curing agent that can be used in the epoxy resin composition of the present invention include phenol compounds mentioned as so-called novolac phenol resins, for example, bisphenol compounds such as bisphenol A, bisphenol F, bisphenol C, bisphenol K, bisphenol Z, bisphenol S, tetramethyl bisphenol A, tetramethyl bisphenol F, tetramethyl bisphenol S, tetramethyl bisphenol Z, tetrabromobisphenol A, dihydroxydiphenylsulfide and 4,4′-thiobis(3-methyl-6-t-butylphenol), dihydroxybenzene compounds such as catechol, resorcin, methylresorcin, hydroquinone, monomethylhydroquinone, dimethylhydroquinone, trimethylhydroquinone, mono-t-butylhydroquinone and di-t-butylhydroquinone, hydroxynaphthalene compounds such as dihydroxynaphthalene, dihydroxymethylnaphthalene, dihydroxymethylnaphthalene and trihydroxynaphthalene, phosphorus-containing phenol curing agents such as LC-950PM60 (manufactured by Shin-AT&C Co., Ltd.), phenol novolac resins such as Shonol BRG-555 (manufactured by Aica Kogyo Co., Ltd.), cresol novolac resins such as DC-5 (manufactured by Nippon Steel Chemical & Material Co., Ltd.), triazine backbone-containing phenol resins, aromatic modified phenol novolac resins, bisphenol A novolac resins, trishydroxyphenylmethane-type novolac resins such as Resitop TPM-100 (manufactured by Gunei Chemical Industry Co., Ltd.), condensates of phenol compounds, naphthol compounds and/or bisphenol compounds with aldehyde compounds, such as naphthol novolac resins, condensates of phenol compounds, phenol compounds and/or naphthol compounds and/or bisphenol compounds with xylylene glycols, such as SN-160, SN-395 and SN-485 (manufactured by Nippon Steel Chemical & Material Co., Ltd.), condensates of phenol compounds and/or naphthol compounds with isopropenylacetophenone, reaction products of phenol compounds and/or naphthol compounds and/or bisphenol compounds with dicyclopentadienes, reaction products of phenol compounds and/or naphthol compounds and/or bisphenol compounds with divinylbenzenes, reaction products of phenol compounds and/or naphthol compounds and/or bisphenol compounds with terpene compounds, and condensates of phenol compounds and/or naphthol compounds and/or bisphenol compounds with biphenyl-based crosslinking agents, as well as polybutadiene-modified phenol resins and phenol resins having spiro rings. A phenol novolac resin, a dicyclopentadiene-type phenol resin, a trishydroxyphenylmethane-type novolac resin, an aromatic modified phenol novolac resin, and the like are preferable from the viewpoint of availability.

The phenol novolac resin can be obtained from the phenol compound and the crosslinking agent. Examples of the phenol compound include phenol, cresol, xylenol, butylphenol, amylphenol, nonylphenol, butylmethylphenol, trimethylphenol and phenylphenol, as well as 1-naphthol and 2-naphthol, and further include bisphenol compounds exemplified with respect to the phenol resin-based curing agent, as others. Examples of the aldehyde compound as the crosslinking agent include formaldehyde, acetaldehyde, propylaldehyde, butylaldehyde, valeraldehyde, capronaldehyde, benzaldehyde, chloraldehyde, bromaldehyde, glyoxal, malonaldehyde, succinaldehyde, glutaraldehyde, adipinaldehyde, pimelinaldehyde, sebacinaldehyde, acrolein, crotonaldehyde, salicylaldehyde, phthalaldehyde and hydroxybenzaldehyde. Examples of the biphenyl-based crosslinking agent include bis(methylol)biphenyl, bis(methoxymethyl)biphenyl, bis(ethoxymethyl)biphenyl and bis(chloromethyl)biphenyl.

Specific examples of the acid anhydride-based curing agent include maleic anhydride, methyltetrahydrophthalic anhydride, hexahydrophthalic anhydride, 4-methylhexahydrophthalic anhydride, methylbicyclo[2.2.1]heptane-2,3-dicarboxylic anhydride, bicyclo[2.2.1]heptane-2,3-dicarboxylic anhydride, 1,2,3,6-tetrahydrophthalic anhydride, pyromellitic anhydride, phthalic anhydride, trimellitic anhydride, methylnadic acid, copolymerized products of styrene monomers and maleic anhydrides, and copolymerized products of indene compounds and maleic anhydrides.

Specific examples of the amine-based curing agent include amine-based compounds, for example, aromatic amine compounds such as diethylenetriamine, triethylenetetramine, m-xylenediamine, isophoronediamine, diaminodiphenylmethane, diaminodiphenylsulfone, diaminodiphenyl ether, benzyldimethylamine, 2,4,6-tris(dimethylaminomethyl)phenol, polyetheramine, biguanide compounds, dicyandiamide and anisidine, and polyamideamines such as condensates of acid compounds such as dimer acids with polyamine compounds.

The cyanate ester compound is not particularly limited as long as it is a compound having two or more cyanate groups (cyanic acid ester groups) in one molecule. Examples include novolac-type cyanate ester-based curing agents such as phenol novolac-type and alkylphenol novolac-type curing agents, naphtholaralkyl-type cyanate ester-based curing agents, biphenylalkyl-type cyanate ester-based curing agents, dicyclopentadiene-type cyanate ester-based curing agents, bisphenol-type cyanate ester-based curing agents such as bisphenol A-type, bisphenol F-type, bisphenol E-type, tetramethyl bisphenol F-type and bisphenol S-type curing agents, and prepolymers obtained by partial triazination of such curing agents. Specific examples of such cyanate ester-based curing agents include bifunctional cyanate resins such as bisphenol A dicyanate, polyphenol cyanate (oligo(3-methylene-1,5-phenylenecyanate), bis(3-methyl-4-cyanatephenyl)methane, bis(3-ethyl-4-cyanatephenyl)methane, bis(4-cyanatephenyl)-1,1-ethane, 4,4-dicyanate-diphenyl, 2,2-bis(4-cyanatephenyl)-1,1,1,3,3,3-hexafluoropropane, 4,4′-methylenebis(2,6-dimethylphenyl cyanate), 4,4′-ethylidenediphenyl dicyanate, hexafluorobisphenol A dicyanate, 2,2-bis(4-cyanate)phenylpropane, 1,1-bis(4-cyanatephenylmethane), bis(4-cyanate-3,5-dimethylphenyl)methane, 1,3-bis(4-cyanatephenyl-1-(methylethylidene))benzene, bis(4-cyanatephenyl)thio ether and bis(4-cyanatephenyl)ether, cyanic acid esters of trihydric phenols, such as tris(4-cyanatephenyl)-1,1,1-ethane and bis(3,5-dimethyl cyanatephenyl)-4-cyanatephenyl-1,1,1-ethane, polyfunctional cyanate resins derived from phenol resins respectively having phenol novolac, cresol novolac, and dicyclopentadiene structures, and prepolymers obtained by partial triazination of such cyanate resins. These can be used singly or in combinations of two or more kinds thereof.

The active ester-based curing agent here used, but not particularly limited, is generally preferably a compound having two or more ester groups high in reaction activity in one molecule, such as a phenol ester compound, a thiophenol ester compound, an N-hydroxyamine ester compound, or an ester compound of a heterocyclic hydroxy compound. The active ester-based curing agent is preferably obtained by a condensation reaction of a carboxylic acid compound and/or a thiocarboxylic acid compound with a hydroxy compound and/or a thiol compound. The curing agent is preferably an active ester-based curing agent obtained from a carboxylic acid compound and a hydroxy compound, more preferably an active ester-based curing agent obtained from a carboxylic acid compound and a phenol compound and/or a naphthol compound, particularly from the viewpoint of an enhancement in heat resistance. Examples of the carboxylic acid compound include benzoic acid, acetic acid, succinic acid, maleic acid, itaconic acid, phthalic acid, isophthalic acid, terephthalic acid and pyromellitic acid. Examples of the phenol compound or the naphthol compound include hydroquinone, resorcin, bisphenol A, bisphenol F, bisphenol S, phenolphthalin, methylated bisphenol A, methylated bisphenol F, methylated bisphenol S, phenol, o-cresol, m-cresol, p-cresol, catechol, α-naphthol, β-naphthol, 1,5-dihydroxynaphthalene, 1,6-dihydroxynaphthalene, 2,6-dihydroxynaphthalene, dihydroxybenzophenone, trihydroxybenzophenone, tetrahydroxybenzophenone, phloroglucin, benzene triol, dicyclopentadienyl diphenol, phenol novolac, and the polyvalent hydroxy compound of the general formula (2). Such active ester-based curing agents can be used singly or in combinations of two or more kinds thereof. The active ester-based curing agent is, specifically, an active ester-based curing agent including a dicyclopentadienyl diphenol structure, an active ester-based curing agent including a naphthalene structure, an active ester-based curing agent as an acetylated product of phenol novolac, or an active ester-based curing agent as a benzoylated product of phenol novolac, in particular, more preferably an active ester-based curing agent including a dicyclopentadienyl diphenol structure, for example, the polyvalent hydroxy compound of the general formula (2), from the viewpoint of an excellent enhancement in peel strength.

Specific examples of other curing agents include phosphine compounds such as triphenylphosphine, phosphonium salts such as tetraphenylphosphonium bromide, imidazole compounds such as 2-methylimidazole, 2-phenylimidazole, 2-ethyl-4-methylimidazole, 2-undecylimidazole and 1-cyanoethyl-2-methylimidazole, imidazole salt compounds as salts of imidazole compounds with trimellitic acid, isocyanuric acid or boron, quaternary ammonium salts such as trimethylammonium chloride, diazabicyclo compounds, salt compounds of diazabicyclo compounds with phenol compounds or phenol novolac resin compounds, complex compounds of boron trifluoride with amine compounds or ether compounds, aromatic phosphonium or iodonium salts.

A curing accelerator can be, if necessary, used in the epoxy resin composition. Examples of the curing accelerator that can be used include imidazole compounds such as 2-methylimidazole, 2-ethylimidazole, 2-ethyl-4-methylimidazole, tertiary amine compounds such as 4-dimethylaminopyridine, 2-(dimethylaminomethyl)phenol and 1,8-diaza-bicyclo(5,4,0)undecene-7, phosphine compounds such as triphenylphosphine, tricyclohexylphosphine and triphenylphosphine triphenylborane, and metal compounds such as tin octylate. When such a curing accelerator is used, the amount of use thereof is preferably 0.02 to 5 parts by mass based on 100 parts by mass of the epoxy resin component in the epoxy resin composition of the present invention. Such a curing accelerator can be used to thereby decrease the curing temperature and shorten the curing time.

An organic solvent or a reactive diluent for viscosity adjustment can be used in the epoxy resin composition.

Examples of the organic solvent include amide compounds such as N,N-dimethylformamide and N,N-dimethylacetamide, ether compounds such as ethylene glycol monomethyl ether, dimethoxydiethylene glycol, ethylene glycol diethyl ether, diethylene glycol diethyl ether and triethylene glycol dimethyl ether, ketone compounds such as acetone, methyl ethyl ketone, methyl isobutyl ketone and cyclohexanone, alcohol compounds such as methanol, ethanol, 1-methoxy-2-propanol, 2-ethyl-1-hexanol, benzyl alcohol, ethylene glycol, propylene glycol, butyl diglycol and pine oil, acetate compounds such as butyl acetate, methoxybutyl acetate, methyl cellosolve acetate, cellosolve acetate, ethyl diglycol acetate, propylene glycol monomethyl ether acetate, carbitol acetate and benzyl alcohol acetate, benzoate compounds such as methyl benzoate and ethyl benzoate, cellosolve compounds such as methyl cellosolve, cellosolve and butyl cellosolve, carbitol compounds such as methylcarbitol, carbitol and butylcarbitol, aromatic hydrocarbon compounds such as benzene, toluene and xylene, dimethylsulfoxide, acetonitrile, and N-methylpyrrolidone, but not limited thereto.

Examples of the reactive diluent include monofunctional glycidyl ether compounds such as allyl glycidyl ether, butyl glycidyl ether, 2-ethylhexyl glycidyl ether, phenyl glycidyl ether and tolyl glycidyl ether, and monofunctional glycidyl ester compounds such as neodecanoic acid glycidyl ester, but not limited thereto.

Such organic solvents or reactive diluents are preferably used singly or as a mixture of a plurality of kinds thereof in a non-volatile content of 90% by mass or less, and the proper types and amounts of use thereof are appropriately selected depending on applications. For example, a polar solvent having a boiling point of 160° C. or less, such as methyl ethyl ketone, acetone or 1-methoxy-2-propanol is preferable in a printed-wiring board application, and the amount of use thereof, in terms of non-volatile content, is preferably 40 to 80% by mass. For example, a ketone compound, an acetate compound, a carbitol compound, an aromatic hydrocarbon compound, dimethylformamide, dimethylacetamide or N-methylpyrrolidone is preferably used in an adhesion film application, and the amount of use thereof, in terms of non-volatile content, is preferably 30 to 60% by mass.

Any other thermosetting resin or thermoplastic resin may be compounded in the epoxy resin composition as long as no characteristics are impaired. Examples include reactive functional group-containing alkylene resins such as a phenol resin, a benzoxazine resin, a bismaleimide resin, a bismaleimide triazine resin, an acrylic resin, a petroleum resin, an indene resin, a coumarone-indene resin, a phenoxy resin, a polyurethane resin, a polyester resin, a polyamide resin, a polyimide resin, a polyamideimide resin, a polyetherimide resin, a polyphenylene ether resin, a modified polyphenylene ether resin, a polyethersulfone resin, a polysulfone resin, a polyether ether ketone resin, a polyphenylenesulfide resin, a polyvinyl formal resin, a polysiloxane compound and hydroxyl group-containing polybutadiene, but not limited thereto.

Various known flame retardants can be each used in the epoxy resin composition, for the purpose of an enhancement in flame retardance of a cured product obtained. Examples of such a usable flame retardant include a halogen-based flame retardant, a phosphorus-based flame retardant, a nitrogen-based flame retardant, a silicone-based flame retardant, an inorganic flame retardant and an organic metal salt-based flame retardant. A halogen-free flame retardant is preferable and a phosphorus-based flame retardant is particularly preferable, from the viewpoint of the environment. Such flame retardants may be used singly or in combinations of two or more kinds thereof.

The phosphorus-based flame retardant here used can be any of an inorganic phosphorus-based compound and an organic phosphorus-based compound. Examples of the inorganic phosphorus-based compound include red phosphorus, ammonium phosphate compounds such as monoammonium phosphate, diammonium phosphate, triammonium phosphate and ammonium polyphosphate, and inorganic nitrogen-containing phosphorus compounds such as phosphoric amide. Examples of the organic phosphorus-based compound include aliphatic phosphate, a phosphate compound, a condensed phosphate compound such as PX-200 (manufactured by Daihachi Chemical Industry Co., Ltd.), a phosphazene, a phosphonic acid compound, a phosphinic acid compound, a phosphine oxide compound, a phosphorane compound, an universal organic phosphorus-based compound such as an organic nitrogen-containing phosphorus compound, and a metal salt of phosphinic acid, as well as a cyclic organic phosphorus compound such as 9,10-dihydro-9-oxa-10-phosphaphenanthrene-10-oxide, 10-(2,5-dihydrooxyphenyl)-10H-9-oxa-10-phosphaphenanthrene-10-oxide and 10-(2,7-dihydrooxynaphthyl)-10H-9-oxa-10-phosphaphenanthrene-10-oxide, and a phosphorus-containing epoxy resin and a phosphorus-containing curing agent which are derivatives each obtained by a reaction of such a cyclic organic phosphorus compound with a compound such as an epoxy resin or a phenol resin.

The amount of compounding of the flame retardant is appropriately selected depending on the type of the phosphorus-based flame retardant, each component of the epoxy resin composition, and the desired degree of flame retardance. For example, the phosphorus content in the organic component (except for the organic solvent) in the epoxy resin composition is preferably 0.2 to 4% by mass, more preferably 0.4 to 3.5% by mass, further preferably 0.6 to 3% by mass. A low phosphorus content may make it difficult to ensure flame retardance, and a too high phosphorus content may have an adverse effect on heat resistance. When the phosphorus-based flame retardant is used, a flame retardant aid such as magnesium hydroxide may be used in combination.

A filler can be, if necessary, used in the epoxy resin composition. Specific examples include molten silica, crystalline silica, alumina, silicon nitride, aluminum hydroxide, boehmite, magnesium hydroxide, talc, mica, calcium carbonate, calcium silicate, calcium hydroxide, magnesium carbonate, barium carbonate, barium sulfate, boron nitride, carbon, a carbon fiber, a glass fiber, an alumina fiber, a silica/alumina fiber, a silicon carbide fiber, a polyester fiber, a cellulose fiber, an aramid fiber, a ceramic fiber, fine particle rubber, silicone rubber, a thermoplastic elastomer, carbon black and a pigment. Examples of the reason for use of the filler generally include the effect of an enhancement in impact resistance. When a metal hydroxide such as aluminum hydroxide, boehmite or magnesium hydroxide is used, it has the effect of acting as a flame retardant aid and enhancing flame retardance. The amount of compounding of such a filler is preferably 1 to 150% by mass, more preferably 10 to 70% by mass based on the entire of the epoxy resin composition. A large amount of compounding may cause deterioration in adhesiveness necessary for a laminated board application and furthermore may result in a brittle cured product and impart no sufficient mechanical properties. A small amount of compounding is liable not to have any effect by compounding of a filler, for example, an enhancement in impact resistance of a cured product.

When the epoxy resin composition is formed into a plate substrate or the like, a filler here used is preferably, for example, fibrous in terms of dimension stability and bending strength, and, for example, a glass fiber substrate where a glass fiber is woven in a net-like manner is more preferable.

Into the epoxy resin composition, various additives such as a silane coupling agent, an antioxidant, a release agent, a defoamer, an emulsifier, a thixotropy imparting agent, a lubricating agent, a flame retardant and a pigment can be further compounded, if necessary. The amount of compounding of such an additive is preferably in the range of 0.01 to 20% by mass relative to the epoxy resin composition.

A fibrous base material can be impregnated with the epoxy resin composition, to thereby produce a prepreg for use in a printed-wiring board or the like. The fibrous base material here used can be, for example, a woven fabric or a non-woven fabric of an inorganic fiber such as glass, or an organic fiber such as a polyester resin, a polyamine resin, a polyacrylic resin, a polyimide resin or an aromatic polyamide resin, but not limited thereto. The method for producing the prepreg from the epoxy resin composition is not particularly limited, and the prepreg is obtained by, for example, immersion in and impregnation with a resin varnish made by adjustment of the viscosity of the epoxy resin composition by an organic solvent, and then heating and drying for semi-curing (B-staging) of a resin component, and, for example, such heating and drying can be made at 100 to 200° C. for 1 to 40 minutes. The amount of the resin in the prepreg, in terms of resin content, is preferably 30 to 80% by mass.

The curing of the prepreg can be made by a method for curing a laminated board, generally used in production of a printed-wiring board, but not limited thereto. For example, when a laminated board is formed using the prepreg, one or more of the prepregs is/are laminated, metal foil is placed on one of or both sides of the prepregs to thereby form a laminated product, and the laminated product is heated and pressurized for lamination and integration. The metal foil here used can be any foil of a single metal, an alloy, and a composite, such as copper, aluminum, brass, and nickel. The laminated product made is then pressurized and heated to thereby cure the prepregs, and thus a laminated board can be obtained. Preferably, the heating temperature is 160 to 220° C., the pressure applied is 50 to 500 N/cm², and the heating and pressurizing time is 40 to 240 minutes, and thus an objective cured product can be obtained. A low heating temperature may cause progression of no sufficient curing reaction, and a high heating temperature may cause the start of pyrolysis of the epoxy resin composition. A low pressure applied may cause bubbles to remain in such a laminated board to result in deterioration in electric characteristics, and a high pressure applied may cause resin flowing before curing, not providing a laminated board having a desired thickness. Furthermore, a short heating and pressurizing time is not preferable because it may cause progression of no sufficient curing reaction, and a long heating and pressurizing time is not preferable because it may cause pyrolysis of the epoxy resin composition in the prepregs.

The epoxy resin composition can be cured by the same method as in a known epoxy resin composition, to thereby obtain an epoxy resin-cured product. The method for obtaining the cured product can be the same method as in a known epoxy resin composition, and a method suitably used is, for example, a method for obtaining a laminated board by, for example, cast molding, injection, potting, dipping, drip coating, transfer molding or compression molding, or lamination of a form of, for example, a resin sheet, copper foil provided with a resin, or prepreg, and then curing with heating and pressurizing. The curing temperature is usually 100 to 300° C., and the curing time is usually about 1 hour to 5 hours.

The epoxy resin-cured product of the present invention can be in the form of, for example, a laminated product, a shaped product, an adhesion product, a coating film, or a film.

The epoxy resin composition is produced, and heated and cured, and a laminated board and a cured product are evaluated, and as a result, the cured product exhibits excellent low-dielectric properties, and furthermore an epoxy-curable resin composition excellent in copper foil peel strength and interlayer cohesion strength in a printed-wiring board application can be provided.

### EXAMPLES

The present invention is specifically described with reference to Examples and Comparative Examples, but the present invention is not limited thereto. Unless particularly noted, “parts” represents “parts by mass”, “%” represents “% by mass”, and “ppm” represents “ppm by mass”. Measurement methods were respectively the following measurement methods.
Hydroxyl equivalent: measured in accordance with JIS K 0070 standard, where the unit was expressed by “g/eq.”. Unless particularly noted, the hydroxyl equivalent of a phenol resin means the phenolic hydroxyl equivalent.
Softening point: measured in accordance with a ring-and-ball method in JIS K 7234 standard. Specifically, an automatic softening point apparatus (ASP-MG4 manufactured by Meitech Company, Ltd.) was used.
Epoxy equivalent:

The epoxy equivalent was measured in accordance with JIS K 7236 standard, where the unit was expressed by “g/eq.”. Specifically, an automatic potentiometric titrator (COM-1600ST manufactured by Hiranuma Sangyo Co., Ltd.) was used, chloroform was used as a solvent, a tetraethylammonium bromide-acetic acid solution was added, and titration with a 0.1 mol/L perchloric acid-acetic acid solution was made.
Total content of chlorine:

The total content of chlorine was measured in accordance with JIS K 7243-3 standard, where the unit was expressed by “ppm”. Specifically, diethylene glycol monobutyl ether was used as a solvent, a 1 mol/L potassium hydroxide-1,2-propane diol solution was added and heat-treated, and thereafter titration with a 0.01 mol/L silver nitrate solution was made with an automatic potentiometric titrator (COM-1700 manufactured by Hiranuma Sangyo Co., Ltd.).
Copper foil peel strength and interlayer adhesion force: measured in accordance with JIS C 6481. The interlayer adhesion force was measured by pulling and peeling between the seventh layer and the eighth layer.
Flame retardance:

The flame retardance was evaluated by a vertical method according to UL94. The evaluation results were recorded as any of V-0, V-1 and V-2.
Glass transition temperature (Tg):

The glass transition temperature was expressed by a temperature of DSCTgm (intermediate temperature in a displacement curve to tangent lines with respect to a glass state and a rubber state) determined in measurement in a temperature rise condition of 20° C./min with a differential scanning calorimeter (EXSTAR6000 DSC6200 manufactured by Hitachi High-Tech Science Corporation) according to IPC-TM-6502.4.25.c.
Relative permittivity and dielectric tangent: evaluated by determining the relative permittivity and the dielectric tangent at a frequency of 1 GHz by a capacitance method according to IPC-TM-650 2.5.5.9 by use of a material analyzer (manufactured by AGILENT Technologies).
GPC (gel permeation chromatography) measurement: columns (TSKgelG4000H_{XL}. TSKgelG3000H_{XL} and TSKgelG2000H_{XL} manufactured by Tosoh Corporation) connected to the main body (HLC-8220 GPC manufactured by Tosoh Corporation) in series were used, and the column temperature was 40° C. The eluent here used was tetrahydrofuran (THF) at a flow rate of 1 mL/min, and the detector here used was a differential refractive index detector. The measurement specimen here used was 50 μL of one obtained by dissolving 0.1 g of a sample in 10 mL of THF and filtering the solution by a micro filter. GPC-8020 Model II version 6.00 manufactured by Tosoh Corporation was used for data processing.
IR: the absorbance at a wavenumber of 650 to 4000 cm⁻¹ was measured with a Fourier transform infrared spectrometer (Spectrum One FT-IR Spectrometer 1760X manufactured by Perkin Elmer Precisely) and KRS-5 as a cell by coating the cell with a sample dissolved in THF and drying the resultant.
ESI-MS: mass analysis was performed by subjecting a sample dissolved in acetonitrile to measurement with a mass spectrometer (LCMS-2020 manufactured by Shimadzu Corporation) by use of acetonitrile and water in a mobile phase.

Abbreviations used in Examples and Comparative Examples are as follows.

[Epoxy Resin]

E1: Epoxy resin obtained in Synthesis Example 1
E2: Epoxy resin obtained in Synthesis Example 2
E3: Epoxy resin obtained in Synthesis Example 3
E4: Biphenylaralkyl-type epoxy resin (NC-3000 manufactured by Nippon Kayaku Co., Ltd., epoxy equivalent 274, softening point 60° C.)
E5: Triphenolmethane-type epoxy resin (EPPN-501H manufactured by Nippon Kayaku Co., Ltd., epoxy equivalent 166)
E6: Phosphorus-containing epoxy resin (FX-1225 manufactured by Nippon Steel Chemical & Material Co., Ltd., epoxy equivalent 317, content rate of phosphorus)
E7: Naphthalene-type epoxy resin (ESN-475V manufactured by Nippon Steel Chemical & Material Co., Ltd., epoxy equivalent 325)
E8: Biphenyl-type epoxy resin (YX-4000H manufactured by Mitsubishi Chemical Group Corporation, epoxy equivalent 195, melting point 105° C.)
E9: Sulfur atom-containing epoxy resin (YSLV-120TE manufactured by Nippon Steel Chemical & Material Co., Ltd., epoxy equivalent 250, melting point 121° C.)
E10: Hydroquinone-type epoxy resin (YDC-1312 manufactured by Nippon Steel Chemical & Material Co., Ltd., epoxy equivalent 176, melting point 142° C.)
E11: Dicyclopentadiene-type epoxy resin (HP-7200H manufactured by DIC Corporation, epoxy equivalent 280, softening point 82° C.)

[Curing Agent]

P1: Phenol novolac resin (BRG-557 manufactured by Aica Sdk Phenol Co., Ltd., hydroxyl group equivalent 105, softening point 85° C.)
P2: Dicyclopentadiene-type phenol resin (GDP-6140 manufactured by Gunei Chemical Industry Co., Ltd., hydroxyl group equivalent 196, softening point 130° C.)
P3: Trishydroxyphenylmethane-type novolac resin (Resitop TPM-100 manufactured by Gunei Chemical Industry Co., Ltd., hydroxyl group equivalent 98, softening point 108° C.)
P4: Biphenylaralkyl-type phenol resin (MEH-7851 manufactured by Meiwa Plastic Industries, Ltd., hydroxyl group equivalent 223, softening point 75° C.)
P5: Naphthol-type curing agent (SN-485 manufactured by Nippon Steel Chemical & Material Co., Ltd., hydroxyl group equivalent 215, softening point 85° C.)
P6: Dicyclopentadiene-type active ester resin obtained in Synthesis Example 4
P7: Dicyandiamide (DIHARD manufactured by Nippon Carbide Industries Co., Ltd., active hydrogen equivalent 21)

[Benzoxazine Resin]

B1: BPF-type benzoxazine resin (F-α-type benzoxazine resin manufactured by Shikoku Chemicals Corporation)

[Curing Accelerator]

C1: 2E4MZ: 2-Ethyl-4-methylimidazole (Curezol 2E4MZ manufactured by Shikoku Chemicals Corporation)
C2: Triphenylphosphine (Hokuko TPP manufactured by Hokko Chemical Industry Co., Ltd.)
C3: 2-Phenylimidazole (Curezol 2PZ manufactured by Shikoku Chemicals Corporation)
C4: 4-Dimethylamino pyridine (manufactured by Kishida Chemical Co., Ltd.)

[Filler]

F1: Hollow glass filler (Glass Bubbles iM30K manufactured by 3M, average particle size (d50) 16 μm)

### Synthesis Example 1

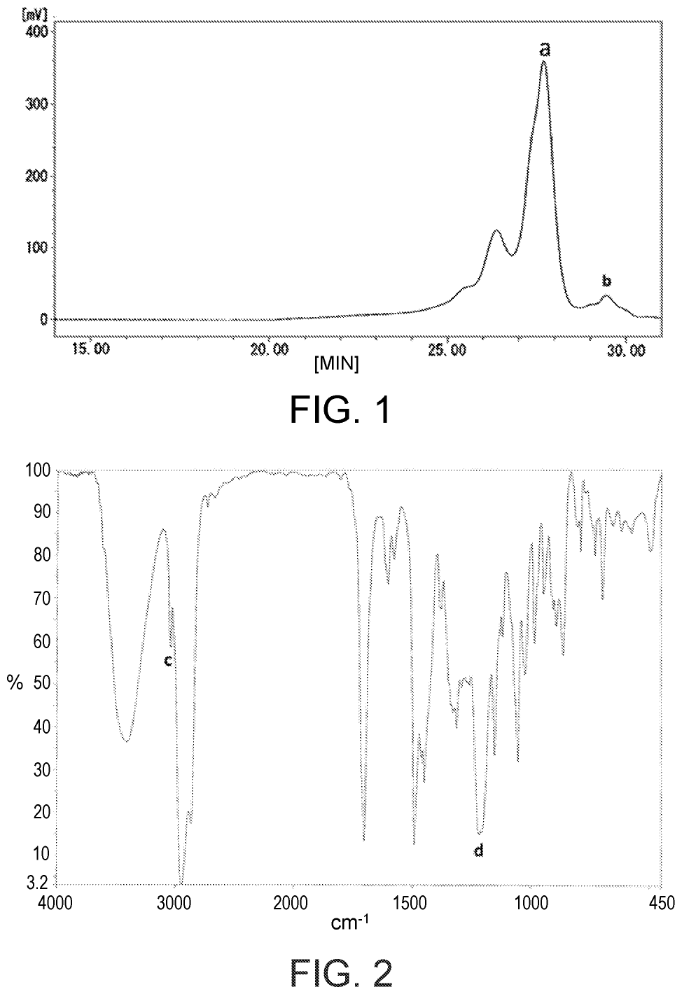

A reaction apparatus equipped with a stirrer, a thermometer, a nitrogen blowing tube, a dropping funnel and a cooling tube was loaded with 140 parts of 2,6-xylenol and 9.3 parts of a 47% BF₃ ether complex (0.1-fold moles relative to dicyclopentadiene initially added), and the resulting mixture was warmed to 110° C. with stirring. While this temperature was kept, 86.6 parts of dicyclopentadiene (0.57-fold moles relative to 2,6-xylenol) was dropped for 1 hour. Furthermore, the reaction was made at a temperature of 110° C. for 3 hours, and thereafter 68 parts of dicyclopentadiene (0.44-fold moles relative to 2,6-xylenol) was dropped for 1 hour while the temperature was kept. Furthermore, the reaction was made at 120° C. for 2 hours. Thereto was added 14.6 parts of calcium hydroxide. Furthermore, 45 parts of an aqueous 10% oxalic acid solution was added. Thereafter, the resultant was warmed to 160° C. for dehydration, and thereafter warmed to 200° C. under a reduced pressure of 5 mmHg, to thereby evaporate and remove the unreacted raw material. A product was dissolved by addition of 700 parts of MIBK, and washed with water by addition of 200 parts of warm water at 80° C., and an aqueous layer as the lower layer was separated and removed. Thereafter, MIBK was evaporated and removed by warming to 160° C. under a reduced pressure of 5 mmHg, and thus 274 parts of red-brown polyvalent hydroxy compound was obtained. The hydroxyl equivalent was 299, the resin had a softening point of 97° C., and the absorption ratio (A₃₀₄₀/A₁₂₁₀) was 0.17. A mass spectrum by ESI-MS (negative) was measured, and the following was confirmed: M-=253, 375, 507, 629. The results of GPC and FT-IR of polyvalent hydroxy compound obtained are respectively illustrated in FIG. 1 and FIG. 2. In GPC, the Mw was 690, the Mn was 510, the content of an n=0 form was 6.5% by area, the content of an n=1 form was 61.5%, and the content of an n≥2 form was 32.0%. In FIG. 1, a is assigned to a mixture of an n=1 form of formula (2) and an n=1 form having no R² adduct, of formula (8), and b is assigned to an n=0 form of formula (2). In FIG. 2, c corresponds to a peak assigned to C—H stretching vibration of an olefin moiety of a dicyclopentadiene backbone, and d means absorption due to C—O stretching vibration of a phenol nucleus.

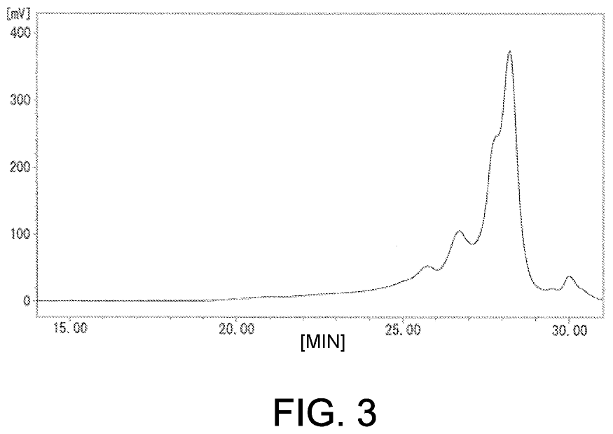

Two hundred parts of the polyvalent hydroxy compound, 309 parts of epichlorohydrin and 93 parts of diethylene glycol dimethyl ether were added to a reaction apparatus equipped with a stirrer, a thermometer, a nitrogen blowing tube, a dropping funnel and a cooling tube, and warmed to 65° C. While the temperature was kept at 63 to 67° C. under a reduced pressure of 125 mmHg, 60 parts of an aqueous 49% sodium hydroxide solution was dropped for 4 hours. In this period, the epichlorohydrin was in an azeotropic state with water and any water flowing out was sequentially removed outside the system. After completion of the reaction, the epichlorohydrin was recovered in conditions of 5 mmHg and 180° C., and 550 parts of MIBK was added to dissolve a solvent. Thereafter, 150 parts of water was added to dissolve a salt as a by-product, the resultant was left to still stand, and a salt solution as the lower layer was separated and removed. After neutralization with an aqueous phosphoric acid solution, a resin solution was washed with water until a water-washing liquid was neutral, and the resultant was filtrated. MIBK was distilled off by warming to 180° C. under a reduced pressure of 5 mmHg, and thus 226 parts of clear red-brown 2,6-xylenol dicyclopentadiene-type epoxy resin (E1) was obtained. The resin had an epoxy equivalent of 358, a total content of chlorine of 520 ppm, and a softening point of 80° C. The results of GPC of epoxy resin (E1) obtained are illustrated in FIG. 3. In GPC, the Mw was 870, the Mn was 570, the content of an m=0 form was 5.5% by area, the content of an m=1 form was 61.8%, and the content of an m≥2 form was 32.6%.

### Synthesis Example 2

The same reaction apparatus as in Synthesis Example 1 was loaded with 140 parts of 2,6-xylenol and 9.3 parts of a 47% BF₃ ether complex (0.1-fold moles relative to dicyclopentadiene initially added), and the resulting mixture was warmed to 110° C. with stirring. While this temperature was kept, 86.6 parts of dicyclopentadiene (0.57-fold moles relative to 2,6-xylenol) was dropped for 1 hour. Furthermore, the reaction was made at a temperature of 110° C. for 3 hours and thereafter 90.6 parts of dicyclopentadiene (0.60-fold moles relative to 2,6-xylenol) was dropped for 1 hour while the temperature was kept. Furthermore, the reaction was made at 120° C. for 2 hours. Thereto was added 14.6 parts of calcium hydroxide. Furthermore, 45 parts of an aqueous 10% oxalic acid solution was added. Thereafter, the resultant was warmed to 160° C. for dehydration, and thereafter warmed to 200° C. under a reduced pressure of 5 mmHg, to thereby evaporate and remove the unreacted raw material. A product was dissolved by addition of 740 parts of MIBK, and washed with water by addition of 200 parts of warm water at 80° C., and an aqueous layer as the lower layer was separated and removed. Thereafter, MIBK was evaporated and removed by warming to 160° C. under a reduced pressure of 5 mmHg, and thus 310 parts of red-brown polyvalent hydroxy compound was obtained. The hydroxyl equivalent was 341, the resin had a softening point of 104° C., and the absorption ratio (A₃₀₄₀/A₁₂₁₀) was 0.27. A mass spectrum by ESI-MS (negative) was measured, and the following was confirmed: M-=253, 375, 507, 629. In GPC, the Mw was 830, the Mn was 530, the content of an n=0 form was 5.9% by area, the content of an n=1 form was 60.1%, and the content of an n≥2 form was 34.0%.

Two hundred parts of the polyvalent hydroxy compound, 271 parts of epichlorohydrin and 81 parts of diethylene glycol dimethyl ether were added to a reaction apparatus, and warmed to 65° C. While the temperature was kept at 63 to 67° C. under a reduced pressure of 125 mmHg, 53 parts of an aqueous 49% sodium hydroxide solution was dropped for 4 hours. In this period, the epichlorohydrin was in an azeotropic state with water and any water flowing out was sequentially removed outside the system. After completion of the reaction, the epichlorohydrin was recovered in conditions of 5 mmHg and 180° C., and 540 parts of MIBK was added to dissolve a solvent. Thereafter, 150 parts of water was added to dissolve a salt as a by-product, the resultant was left to still stand, and a salt solution as the lower layer was separated and removed. After neutralization with an aqueous phosphoric acid solution, a resin solution was washed with water until a water-washing liquid was neutral, and the resultant was filtrated. MIBK was distilled off by warming to 180° C. under a reduced pressure of 5 mmHg, and thus 221 parts of clear red-brown 2,6-xylenol dicyclopentadiene-type epoxy resin (E2) was obtained. The resin had an epoxy equivalent of 421, a total content of chlorine of 530 ppm, and a softening point of 84° C. In GPC, the Mw was 880, the Mn was 570, the content of an m=0 form was 5.5% by area, the content of an m=1 form was 58.8%, and the content of an m≥2 form was 35.7%.

### Synthesis Example 3

The same reaction apparatus as in Synthesis Example 1 was loaded with 140 parts of 2,6-xylenol and 9.3 parts of a 47% BF₃ ether complex (0.1-fold moles relative to dicyclopentadiene initially added), and the resulting mixture was warmed to 110° C. with stirring. While this temperature was kept, 86.6 parts of dicyclopentadiene (0.57-fold moles relative to 2,6-xylenol) was dropped for 1 hour. Furthermore, the reaction was made at a temperature of 110° C. for 3 hours, and thereafter, while this temperature was kept, 56.7 parts of dicyclopentadiene (0.37-fold moles relative to 2,6-xylenol) was dropped for 1 hour. Furthermore, the reaction was made at a temperature of 120° C. for 2 hours. Thereto was added 14.6 parts of calcium hydroxide. Furthermore, 45 parts of an aqueous 10% oxalic acid solution was added. Thereafter, the resultant was warmed to 160° C. for dehydration, and thereafter warmed to 200° C. under a reduced pressure of 5 mmHg, to thereby evaporate and remove the unreacted raw material. A product was dissolved by addition of 660 parts of MIBK, and washed with water by addition of 200 parts of warm water at 80° C., and an aqueous layer as the lower layer was separated and removed. Thereafter, MIBK was evaporated and removed by warming to 160° C. under a reduced pressure of 5 mmHg, and thus 280 parts of red-brown polyvalent hydroxy compound was obtained. The hydroxyl equivalent was 272, the resin had a softening point of 91° C., and the absorption ratio (A₃₀₄₀/A₁₂₁₀₀) was 0.14. A mass spectrum by ESI-MS (negative) was measured, and the following was confirmed: M-=253, 375, 507, 629. In GPC, the Mw was 680, the Mn was 530, the content of an n=0 form was 5.9% by area, the content of an n=1 form was 75.1%, and the content of an n≥2 form was 19.0%.

Two hundred parts of the polyvalent hydroxy compound, 170 parts of epichlorohydrin and 51 parts of diethylene glycol dimethyl ether were added to a reaction apparatus, and warmed to 65° C. While the temperature was kept at 63 to 67° C. under a reduced pressure of 125 mmHg, 66 parts of an aqueous 49% sodium hydroxide solution was dropped for 4 hours. In this period, the epichlorohydrin was in an azeotropic state with water and any water flowing out was sequentially removed outside the system. After completion of the reaction, the epichlorohydrin was recovered in conditions of 5 mmHg and 180° C., and 560 parts of MIBK was added to dissolve a solvent. Thereafter, 150 parts of water was added to dissolve a salt as a by-product, the resultant was left to still stand, and a salt solution as the lower layer was separated and removed. After neutralization with an aqueous phosphoric acid solution, a resin solution was washed with water until a water-washing liquid was neutral, and the resultant was filtrated. MIBK was distilled off by warming to 180° C. under a reduced pressure of 5 mmHg, and thus 229 parts of clear red-brown 2,6-xylenol. dicyclopentadiene-type epoxy resin (E3) was obtained. The resin had an epoxy equivalent of 358, a total content of chlorine of 570 ppm, and a softening point of 76° C. In GPC, the Mw was 800, the Mn was 470, the content of an m=0 form was 4.6% by area, the content of an m=1 form was 63.2%, and the content of an m≥2 form was 32.2%.

### Synthesis Example 4

The same reaction apparatus as in Synthesis Example 1 was loaded with 400 parts of phenol and 7.5 parts of a 47% BF₃ ether complex, and the resulting mixture was warmed to 70° C. with stirring. While this temperature was kept, 70.2 parts of dicyclopentadiene was dropped for 2 hours. Furthermore, the reaction was made at a temperature of 125 to 135° C. for 4 hours, and 11.7 parts of calcium hydroxide was added thereto. Furthermore, 35 parts of an aqueous 10% oxalic acid solution was added. Thereafter, the resultant was warmed to 160° C. for dehydration, and thereafter warmed to 200° C. under a reduced pressure of 5 mmHg, to thereby evaporate and remove the unreacted raw material. A product was dissolved by addition of 1097 parts of MIBK, and washed with water by addition of 108 parts of 80° C. at warm water, and an aqueous layer as the lower layer was separated and removed. Thereafter, MIBK was evaporated and removed by warming to 160° C. under a reduced pressure of 5 mmHg, and thus 158 parts of red-brown polyvalent hydroxy compound was obtained. The hydroxyl equivalent was 177 and the softening point was 92° C.

A reaction apparatus was loaded with 64.8 parts of the polyvalent hydroxy compound, 17.4 parts of 1-naphthol, 0.01 parts of tetra-n-butylammonium bromide, 49.4 parts of isophthalic acid chloride, and 329 parts of toluene, and the resulting mixture was heated to 50° C. and dissolved. While the system was controlled at 60° C. or less, 97.3 parts of an aqueous 20% sodium hydroxide solution was dropped for 3 hours and thereafter stirring was continued at the temperature for 1 hour. The reaction mixture was left to still stand and separated, and an aqueous layer was removed. The operation was repeated until the pH of the aqueous layer reached 7. Thereafter, the water content was removed by dehydration under reflux, and thus 161 parts of active ester resin (P6) in the form of a toluene solution having a non-volatile content of 65% was obtained. The active ester equivalent calculated from the amount of loading of each raw material was 235.

### Example 1

One hundred parts of E1 as an epoxy resin, 37 parts of P1 as a curing agent, and 0.22 parts of C1 as a curing accelerator were compounded, and dissolved in a mixed solvent adjusted from MEK, propylene glycol monomethyl ether and N,N-dimethylformamide, to thereby obtain an epoxy resin composition varnish. A glass cloth (WEA 7628 XS13 manufactured by Nitto Boseki Co., Ltd., 0.18 mm in thickness) was impregnated with the epoxy resin composition varnish obtained. The glass cloth impregnated was dried in a hot air oven at 150° C. for 9 minutes, to thereby obtain a prepreg. Eight of the prepregs obtained and copper foil (3EC-III manufactured by Mitsui Mining & Smelting Co., Ltd., thickness 35 μm) were stacked with the copper foil being located on and below the prepregs, and the resulting stacked product was pressed in vacuum at 2 MPa in temperature conditions of 130° C. x 15 minutes+190° C.×80 minutes, to thereby obtain a laminated board having a thickness of 1.6 mm. The results of the copper foil peel strength and interlayer adhesion force of the laminated board are shown in Table 1.

The prepregs obtained were ground, to thereby provide a ground prepreg powder by passing through a 100-mesh sieve. The prepreg powder obtained was placed into a fluororesin mold, and pressed in vacuum at 2 MPa in temperature conditions of 130° C. x 15 minutes+190° C. x 80 minutes, to thereby obtain a test piece of 50 mm square x 2 mm thickness. The results of the relative permittivity and dielectric tangent in the test piece are shown in Table 1.

### Examples 2 to 11 and Comparative Examples 1 to 12

Each laminated board and each test piece were obtained by compounding at each amount of compounding (part(s)) in Tables 1 to 3 and by the same operations performed as in Example 1. The curing accelerator was used in an amount so that the varnish gelation time could be adjusted to about 300 seconds. The same test as in Example 1. The results are shown in Tables 1 to 3.

TABLE 1

| | | | | Comparative | Comparative | Comparative | Comparative |
|---|---|---|---|---|---|---|---|
| | Example 1 | Example 2 | Example 3 | Example 1 | Example 2 | Example 3 | Example 4 |
| E1 | 100 | | | | | | |
| E2 | | 100 | | | | | |
| E3 | | | 100 | | | | |
| E4 | | | | 100 | | | |
| E5 | | | | | 100 | | |
| E7 | | | | | | 100 | |
| E11 | | | | | | | 100 |
| P1 | 29 | 25 | 29 | 38 | 63 | 32 | 38 |
| C1 | 0.30 | 0.30 | 0.30 | 0.10 | 0.05 | 0.15 | 0.10 |
| Copper foil | 1.4 | 1.3 | 1.5 | 1.6 | 1.2 | 1.5 | 1.6 |
| peel strength | | | | | | | |
| (kN/m) | | | | | | | |
| Interlayer | 1.2 | 1.0 | 1.3 | 1.3 | 1.0 | 1.3 | 1.2 |
| adhesion force | | | | | | | |
| (kN/m) | | | | | | | |
| Relative | 2.90 | 2.81 | 2.94 | 3.21 | 3.19 | 3.23 | 3.17 |
| permittivity | | | | | | | |
| Dielectric tangent | 0.013 | 0.011 | 0.018 | 0.016 | 0.027 | 0.011 | 0.021 |
| Tg (° C.) | 168 | 161 | 162 | 154 | 208 | 133 | 184 |

TABLE 2

| | | | | | | Comparative | Comparative | Comparative |
|---|---|---|---|---|---|---|---|---|
| | Example 4 | Example 5 | Example 6 | Example 7 | Example 8 | Example 7 | Example 8 | Example 9 |
| E2 | 100 | 100 | 100 | 100 | 100 | | | |
| E11 | | | | | | 100 | 100 | 100 |
| P2 | 47 | | | | | | | |
| P3 | | 23 | | | | | | |
| P4 | | | 53 | | | 80 | | |
| P5 | | | | 51 | | | 77 | |
| P6 | | | | | 56 | | | 84 |
| C1 | 0.40 | 0.40 | 0.38 | 0.45 | | 0.14 | 0.25 | |
| C4 | | | | | 0.50 | | | 0.50 |
| Copper foil | 1.3 | 1.2 | 1.3 | 1.2 | 1.3 | 1.6 | 1.3 | 1.3 |
| peel strength | | | | | | | | |
| (kN/m) | | | | | | | | |
| Interlayer | 1.0 | 0.9 | 1.0 | 0.9 | 1.3 | 1.2 | 0.9 | 0.9 |
| adhesion force | | | | | | | | |
| (kN/m) | | | | | | | | |
| Relative | 2.78 | 2.81 | 2.78 | 2.76 | 2.74 | 3.08 | 3.10 | 3.01 |
| permittivity | | | | | | | | |
| Dielectric tangent | 0.010 | 0.012 | 0.009 | 0.006 | 0.006 | 0.019 | 0.013 | 0.010 |
| Tg (° C.) | 156 | 173 | 128 | 161 | 155 | 130 | 170 | 166 |

TABLE 3

| | | | | Comparative | Comparative | Comparative |
|---|---|---|---|---|---|---|
| | Example 9 | Example 10 | Example 11 | Example 10 | Example 11 | Example 12 |
| E2 | 100 | 40 | 50 | | | |
| E4 | | 60 | | | 60 | |
| E5 | | | 50 | | | 50 |
| E11 | | | | 100 | 40 | 50 |
| P1 | | | 44 | | | 50 |
| P2 | | 20 | | | 20 | |
| P7 | 2.5 | 1 | | 3.8 | 1 | |
| B1 | | 50 | | | 50 | |
| C1 | | | 0.35 | | | 0.10 |
| C3 | | 0.20 | | | 0.15 | |
| Copper foil | 1.3 | 1.4 | 1.3 | 1.5 | 1.4 | 1.3 |
| peel strength | | | | | | |
| (kN/m) | | | | | | |
| Interlayer | 0.9 | 0.8 | 1.1 | 1.0 | 0.8 | 1.0 |
| adhesion force | | | | | | |
| (kN/m) | | | | | | |
| Relative | 2.75 | 2.95 | 2.98 | 3.02 | 3.15 | 3.19 |
| permittivity | | | | | | |
| Dielectric tangent | 0.009 | 0.011 | 0.018 | 0.018 | 0.015 | 0.025 |
| Tg (° C.) | 182 | 153 | 186 | 195 | 160 | 193 |

### Example 12 and Comparative Examples 13 to 15

Each laminated board and each test piece were obtained by compounding at each amount of compounding (parts) in Table 4 and by the same operations performed as in Example 1. Table 4 shows the measurement results of the flame retardance, copper foil peel strength, interlayer adhesion force and Tg of such each laminated board, as well as the measurement results of the relative permittivity and dielectric tangent of such each test piece.

TABLE 4

| | | Comparative | Comparative | Comparative |
|---|---|---|---|---|
| | Example 12 | Example 13 | Example 14 | Example 15 |
| E2 | 50 | | | |
| E6 | 50 | 50 | 100 | 100 |
| E11 | | 50 | | |
| P1 | | | 33 | |
| P7 | 2.9 | 3.5 | | 3.3 |
| C1 | | | 0.05 | |
| Copper foil peel | 1.5 | 1.5 | 1.7 | 1.6 |
| strength (kN/m) | | | | |
| Interlayer adhesion | 1.0 | 1.0 | 1.3 | 1.0 |
| force (kN/m) | | | | |
| Flame retardance | V-0 | V-1 | V-1 | V-0 |
| Relative permittivity | 2.98 | 3.20 | 3.38 | 3.31 |
| Dielectric tangent | 0.012 | 0.019 | 0.023 | 0.018 |
| Tg (° C.) | 176 | 182 | 137 | 169 |

### Example 13

In order to perform evaluation of a cast molding resin, a resin composition was obtained by kneading 50 parts of E2 and 50 parts of E8 as epoxy resins, 32 parts of P1 as a curing agent, and 1.0 part of C2 as a curing accelerator. The epoxy resin composition obtained was molded at 175° C. and furthermore post-cured at 175° C. for 12 hours, to thereby obtain a cured product. Table 5 shows the measurement results of the relative permittivity, dielectric tangent and Tg of the cured product.

### Examples 14 to 15 and Comparative Examples 16 to 18

Each cured product was obtained by compounding at each amount of compounding (parts) in Table 5 and by the same operations performed as in Example 13. The same test as in Example 13 was performed. The results are shown in Table 5.

TABLE 5

| | | | | Comparative | Comparative | Comparative |
|---|---|---|---|---|---|---|
| | Example 13 | Example 14 | Example 15 | Example 16 | Example 17 | Example 18 |
| E2 | 50 | 50 | 50 | | | |
| E8 | 50 | | | 100 | | |
| E9 | | 50 | | | 100 | |
| E10 | | | 50 | | | 100 |
| P1 | 32 | 33 | 42 | 38 | 42 | 60 |
| C2 | 1.0 | 1.0 | 1.0 | 1.0 | 1.0 | 1.0 |
| F1 | 40 | 40 | 45 | 45 | 45 | 50 |
| Relative | 2.58 | 2.53 | 2.62 | 2.79 | 2.67 | 2.82 |
| permittivity | | | | | | |
| Dielectric | 0.014 | 0.013 | 0.015 | 0.019 | 0.018 | 0.020 |
| tangent | | | | | | |
| Tg (° C.) | 158 | 157 | 163 | 149 | 147 | 158 |

As is clear from the results, an epoxy resin composition of the present invention can provide a resin cured product that exhibits very favorable low-dielectric properties and furthermore that is also excellent in adhesion force.

### INDUSTRIAL APPLICABILITY

The epoxy resin composition of the present invention is excellent in dielectric properties, heat resistance and adhesiveness, can be utilized in various applications of lamination, molding, adhesion, and the like, and is useful particularly as an electronic material for high-speed communication equipment.

1. An epoxy resin composition containing an epoxy resin and a curing agent, wherein the epoxy resin is partially or fully an epoxy resin represented by the following general formula (1): 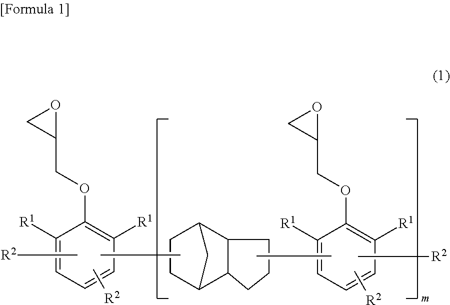
wherein each R¹ independently represents a hydrocarbon group having 1 to 8 carbon atoms, each R² independently represents a hydrogen atom or a dicyclopentenyl group, and at least one R² is a dicyclopentenyl group; and m represents the number of repetitions and an average value thereof is a number of 0 to 5.

2. The epoxy resin composition according to claim 1, wherein the epoxy resin has an epoxy equivalent of 244 to 3700 g/eq.

3. The epoxy resin composition according to claim 1, wherein the curing agent is at least one selected from the group consisting of a phenol resin compound, an acid anhydride compound, an amine compound, a cyanate ester compound, an active ester compound, a hydrazide compound, an acidic polyester compound, or an aromatic cyanate compound.

4. A prepreg using the epoxy resin composition according to claim 1.

5. A laminated board using the epoxy resin composition according to claim 1.

6. A printed-wiring substrate using the epoxy resin composition according to claim 1.

7. A cured product obtained by curing the epoxy resin composition according to claim 1.

8. The epoxy resin composition according to claim 2, wherein the curing agent is at least one selected from the group consisting of a phenol resin compound, an acid anhydride compound, an amine compound, a cyanate ester compound, an active ester compound, a hydrazide compound, an acidic polyester compound, or an aromatic cyanate compound.

9. A prepreg using the epoxy resin composition according to claim 2.

10. A prepreg using the epoxy resin composition according to claim 3.

11. A prepreg using the epoxy resin composition according to claim 8.

12. A laminated board using the epoxy resin composition according to claim 2.

13. A laminated board using the epoxy resin composition according to claim 3.

14. A laminated board using the epoxy resin composition according to claim 8.

15. A printed-wiring substrate using the epoxy resin composition according to claim 2.

16. A printed-wiring substrate using the epoxy resin composition according to claim 3.

17. A printed-wiring substrate using the epoxy resin composition according to claim 8.

18. A cured product obtained by curing the epoxy resin composition according to claim 2.

19. A cured product obtained by curing the epoxy resin composition according to claim 3.

20. A cured product obtained by curing the epoxy resin composition according to claim 8.
